(19) United States
(12) Patent Application Publication
(10) Pub. No.: US 2024/0069430 A1
(43) Pub. Date: Feb. 29, 2024

(54) EXPOSURE MASK, PATTERN FORMING METHOD, AND METHOD OF MANUFACTURING SEMICONDUCTOR DEVICE

(71) Applicant: Kioxia Corporation, Tokyo (JP)

(72) Inventor: Naoki SATO, Yokkaichi Mie (JP)

(73) Assignee: Kioxia Corporation, Tokyo (JP)

(21) Appl. No.: 18/454,222

(22) Filed: Aug. 23, 2023

(30) Foreign Application Priority Data
Aug. 25, 2022 (JP) 2022-134264

(51) Int. Cl. G03F 1/24; G03F 1/54; H01L 21/027

(52) U.S. Cl. CPC G03F 1/24; G03F 1/54; H01L 21/0274

(57) ABSTRACT

An exposure mask includes a substrate having a first main surface and a second main surface, a reflective layer that is provided on the first main surface side and reflects exposure light, and an absorption layer that is provided with a predetermined pattern on the first main surface side via the reflective layer and absorbs the exposure light, in which the reflective layer includes a first region of which a surface height from the second main surface is a first height, and a second region which is adjacent to the first region via a first step on a surface of the reflective layer, and of which a surface height from the second main surface is a second height higher than the first height, and the absorption layer is provided in each of the first region and the second region.

### CROSS-REFERENCE TO RELATED APPLICATION

This application is based upon and claims the benefit of priority from Japanese Patent Application No. 2022-134264, filed Aug. 25, 2022, the entire contents of which are incorporated herein by reference.

### FIELD

Embodiments described herein relate generally to an exposure mask, a pattern forming method, and a method of manufacturing a semiconductor device.

### BACKGROUND

In the method of manufacturing a semiconductor device, patterns may be formed by an exposure process using a reflective exposure mask. By adjusting a distance from a surface of the exposure mask to a surface of a wafer to find a best focus position of the pattern to form the pattern in a photoresist layer on the wafer with an exposure light reflected by the exposure mask, light can be uniformly focused on the photoresist layer across an entire exposed region.

However, wafers that have undergone various processes may have films with local film thickness differences called local steps. When the photoresist layer is formed on such a film and is exposed with the above exposure mask, there are regions where the distance from the surface of the exposure mask to the surface of the wafer varies locally, and it may be difficult to focus light on the entire region of the photoresist layer.

### DESCRIPTION OF THE DRAWINGS

FIG. 1 is a cross-sectional view showing an example of the configuration of a semiconductor device according to at least one embodiment;

FIG. 2 is a cross-sectional view showing an example of the configuration of an exposure mask according to at least one embodiment;

FIG. 3 is a cross-sectional view illustrating part of procedures of a method of manufacturing the semiconductor device according to at least one embodiment;

FIGS. 4A to 4C are cross-sectional views illustrating part of the procedures of the method of manufacturing the semiconductor device according to at least one embodiment;

FIGS. 5A and 5B are cross-sectional views showing an example of procedures of an exposure process using an exposure mask according to a comparative example;

FIGS. 6A and 6B are cross-sectional views showing an example of the procedures of the exposure process using the exposure mask according to the comparative example;

FIG. 7 is a cross-sectional view showing an example of the configuration of an exposure mask according to Modification Example 1 of at least one embodiment;

FIG. 8 is a cross-sectional view showing an example of the configuration of a semiconductor device according to Modification Example 2 of at least one embodiment;

FIG. 9 is a cross-sectional view showing an example of the configuration of an exposure mask according to Modification Example 2 of at least one embodiment; and

FIG. 10 is a cross-sectional view illustrating part of procedures of a method of manufacturing the semiconductor device according to Modification Example 2 of at least one embodiment.

### DETAILED DESCRIPTION

Embodiments provide an exposure mask, a pattern forming method, and a method of manufacturing a semiconductor device capable of focusing light on a photoresist layer formed on a film having a local step.

In general, according to at least one embodiment, an exposure mask includes: a substrate having a first main surface and a second main surface; a reflective layer that is provided on the first main surface side and reflects exposure light; and an absorption layer that is provided with a predetermined pattern on the first main surface side via the reflective layer and absorbs the exposure light, in which the reflective layer includes a first region of which a surface height from the second main surface is a first height, and a second region which is adjacent to the first region via a first step on a surface of the reflective layer, and of which a surface height from the second main surface is a second height higher than the first height, and the absorption layer is provided in each of the first region and the second region.

Hereinafter, embodiments will be described in detail with reference to the accompanying drawings. The present disclosure is not limited by the following embodiments. Components in the following embodiments include components that can be easily assumed by those skilled in the art or substantially the same components. As used herein, “equal” or “uniform” means “equal” or “uniform” to the extent that, for example, manufacturing errors are allowed.

Configuration Example of Semiconductor Device

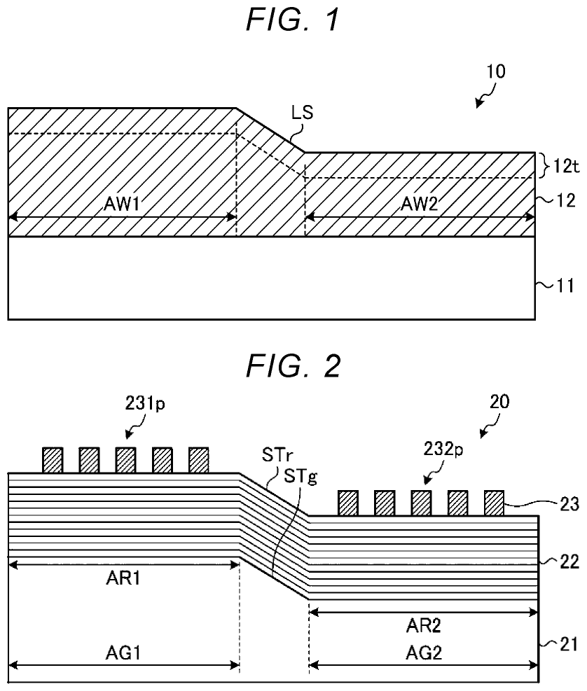

FIG. 1 is a cross-sectional view showing an example of the configuration of a semiconductor device 10 according to an embodiment. More specifically, FIG. 1 is a schematic diagram of a partial region of the semiconductor device 10 during manufacturing, showing a state before exposure and development process, for example.

As shown in FIG. 1, for example, the semiconductor device 10 at a predetermined timing in a manufacturing process includes a substrate 11 made of silicon or the like and a film 12 formed on the substrate 11. That is, the substrate 11 is the body portion of the wafer 1. The film 12 is a multilayer film or the like including a layer to be processed 12t in at least a surface layer portion, and in which a plurality of types of insulating layers, a plurality of types of conductive layers, and the like are stacked.

Various structures constituting the semiconductor device 10 may be formed on the insulating layers and conductive layers through various processes. Through such various processes, the insulating layers and the conductive layers may have different thicknesses for each predetermined region. Thus, the film 12 includes a region AW1 as a sixth region having a predetermined film thickness and a region AW2 as a fifth region having a film thickness thinner than the thickness of the region AW1. The regions AW1 and AW2 are adjacent to each other, and connected in series via a local step LS with a slope on the surface of the film 12, for example.

The regions AW1 and AW2 can have various shapes including a rectangular shape when viewed from above. The minimum width of each of the regions AW1 and AW2 may be, for example, at least about several μm. The film thickness difference of the film 12 in the regions AW1 and AW2 is, for example, 50 nm or more and 100 nm or less. However, the numerical values are only examples, and the sizes of the regions AW1 and AW2 and the difference in film thickness between the regions AW1 and AW2 may vary depending on the processes that the semiconductor device 10 has undergone so far and the stages of the manufacturing process.

Configuration Example of Exposure Mask

FIG. 2 is a cross-sectional view showing an example of the configuration of an exposure mask 20 according to the embodiment. The exposure mask 20 shown in FIG. 2 is an example of an exposure mask used for exposure process of the semiconductor device 10 having the local step LS described above. The exposure process using the exposure mask 20 is performed using, for example, extreme ultraviolet (EUV) as exposure light, and the exposure mask 20 is configured as, for example, a reflective exposure mask. Extreme ultraviolet light is light with a wavelength of 13.5 nm.

FIG. 2 shows a partial region of the exposure mask 20 corresponding to the semiconductor device 10 shown in FIG. 1 described above. The exposure mask 20 shown in FIG. 2 has, for example, an area about four times as large as the corresponding region of the semiconductor device 10 described above. As will be described later, patterns 231p and 232p of the exposure mask 20 are reduced and transferred onto the wafer 1, thereby performing the exposure process of the semiconductor device 10.

More specifically, the exposure mask 20 includes a substrate 21 made of a material such as glass having a small thermal expansion coefficient, a reflective layer 22 formed on the substrate 21, and an absorption layer 23 formed on the reflective layer 22.

The substrate 21 has a substantially flat shape having a main surface as a first main surface on the side on which the reflective layer 22 and the absorption layer 23 are provided, and a main surface as a second main surface on the opposite side. The average thickness of the substrate 21 may be, for example, about several mm.

However, the substrate 21 includes a region AG1 as a fourth region having a predetermined thickness as a second thickness, and a region AG2 as a third region having a thickness thinner than the region AG1 as a first thickness. The regions AG1 and AG2 are adjacent to each other, and connected in series via, for example, a step STg with a gentle slope on the main surface on the reflective layer 22 and absorption layer 23 side.

Here, the region AG1 is provided at a position corresponding to the region AW2 of the semiconductor device 10 described above, and the region AG2 is provided at a position corresponding to the region AW1 of the semiconductor device 10 described above. The step STg may be provided at a position substantially corresponding to the local step LS of the semiconductor device 10 described above.

That the regions AG1 and AG2 correspond to the regions AW2 and AW1 respectively means that during the exposure process described later, a pattern 231p to be described later provided at a position overlapping the region AG1 in the height direction, is transferred to the region AW2 of the semiconductor device 10, and a pattern 232p to be described later provided at a position overlapping the region AG2 in the height direction, is transferred to the region AW1 of the semiconductor device 10.

However, the step STg may be positioned substantially corresponding to the local step LT of the semiconductor device 10, and may not necessarily have a shape similar to the local step LT.

The reflective layer 22 has a multilayer structure in which layers made of different materials that reflect exposure light are alternately stacked. As the layers, for example, a combination may be used in which Mo layers and Si layers are alternately stacked as different types of layers having significantly different refractive indices of exposure light. Thus, the reflection efficiency of the reflective layer 22 can be improved.

The reflective layer 22 has a uniform thickness throughout. The reflective layer 22 can have an average layer thickness of, for example, 250 nm or more and 300 nm or less.

Since the reflective layer 22 is provided on the substrate 21 having the regions AG1 and AG2 with different thicknesses and the step STg, the surface height of the reflective layer 22 from the back surface of the substrate 21 varies depending on the regions AG1 and AG2 and the step STg.

That is, the reflective layer 22 includes a region AR1 as a second region that overlaps with the region AG1 of the substrate 21 in the height direction. In the region AR1, the reflective layer 22 has a predetermined height as a second height, as the surface height from the back surface of the substrate 21. The reflective layer 22 includes a region AR2 as a first region that overlaps with the region AG2 of the substrate 21 in the height direction. In the region AR2, the reflective layer 22 has a predetermined height as a first height, which is lower than the surface height in the region AR1, as the surface height from the back surface of the substrate 21.

The difference in surface height of the reflective layer 22 in the regions AR1 and AR2 is, for example, two times or more and ten times or less the film thickness difference of the film 12 of the semiconductor device 10 described above. As described above, for example, when the film thickness difference of the film 12 is 50 nm or more and 100 nm or less, the surface height difference of the reflective layer 22 in the regions AR1 and AR2 can be set to 120 nm or more and 1000 nm or less. Such a difference in surface height of the reflective layer 22 can be obtained, for example, by adjusting a difference in thickness of the substrate 21 in the regions AG1 and AG2.

The regions AR1 and AR2 can have various shapes including a rectangular shape according to the shapes of the regions AG1 and AG2 of the substrate 21 having similar shapes to the regions AW1 and AW2 of the film 12 of the semiconductor device 10. When the regions AR1 and AR2 are rectangular, for example, the length of one side of each of the regions AR1 and AR2 is, for example, several hundred nm to several mm.

The reflective layer 22 has a step STr as a first step at a position overlapping the step STg of the substrate 21 in the height direction. The step STr is a gentle slope with a predetermined inclination angle along the step STg of the substrate 21.

Specifically, it is preferable that the step STr is a gentle slope with an inclination angle of 0.01° or more and 5° or less. In other words, the size of the step STg provided between the regions AG1 and AG2 is preferably adjusted such that the step STr of the reflective layer 22 has the inclination angle as described above. Thus, the step STr of the reflective layer 22 also has a size corresponding to the size of the step STg of the substrate 21.

The absorption layer 23 is made of a material that absorbs exposure light. As the absorption layer 23, for example, a TaN layer, a TaBN layer, a TaGeN layer, or the like may be used. The absorption layer 23 is respectively provided at positions overlapping the regions AR1 and AR2 of the reflective layer 22 in the height direction. The layer thickness of the absorption layer 23 is the same over the entire region. The absorption layer 23 can have an average layer thickness of, for example, 50 nm or more and 70 nm or less.

The absorption layer 23 has the pattern 231p at a position overlapping with the region AR1 of the reflective layer 22 in the height direction. The absorption layer 23 has the pattern 232p at a position overlapping with the region AR2 of the reflective layer 22 in the height direction. The patterns 231p and 232p may be any patterns such as lines and spaces, holes, or dots. The patterns 231p and 232p are transferred to the semiconductor device 10 by an exposure process to be described later, and become patterns with a size of several tens of nm to several μm, for example.

The exposure mask 20 configured as described above can be manufactured, for example, as follows.

First, the substrate 21 such as a glass substrate having an equal thickness over the entire surface and an average thickness of, for example, several mm is prepared. The substrate 21 is provided with the step STg described above. Such a step STg can be formed using, for example, a focused ion beam (FIB) or the like.

Alternatively, the step STg may be formed by photolithography technology and etching technology. Here, for example, the photoresist layer is formed on the substrate 21 to cover the region AG1 of the substrate 21 and have a skirting shape in the step STg. By etching the surface of the substrate 21 exposed from the photoresist layer, the above-described step STg is formed. As the etching process, for example, anisotropic etching such as reactive ion etching (RIE) may be used.

The substrate 21 including the regions AG1 and AG2 having different thicknesses and the step STg is formed by the above processing.

The reflective layer 22 is formed by alternately stacking, for example, Mo layers and ASi layers on the substrate 21 on which the step STg is formed. Here, the Mo layers and the ASi layers are formed over the entire surface of the substrate 21 to have a uniform layer thickness. Thus, the reflective layer 22 having a step STr on the surface is formed.

A TaN layer, a TaBN layer, a TaGeN layer, or the like which covers the entire surface of the reflective layer 22 is formed. Here, any one of the layers have a uniform layer thickness over the entire surface of the reflective layer 22. The patterns 231p and 232p are formed in the layer formed on the reflective layer 22. The patterns 231p and 232p can be formed using, for example, photolithography technology and etching technology, as described above. Thus, the absorption layer 23 is formed.

As described above, the exposure mask 20 of the embodiment is manufactured.

Method of Manufacturing Semiconductor Device

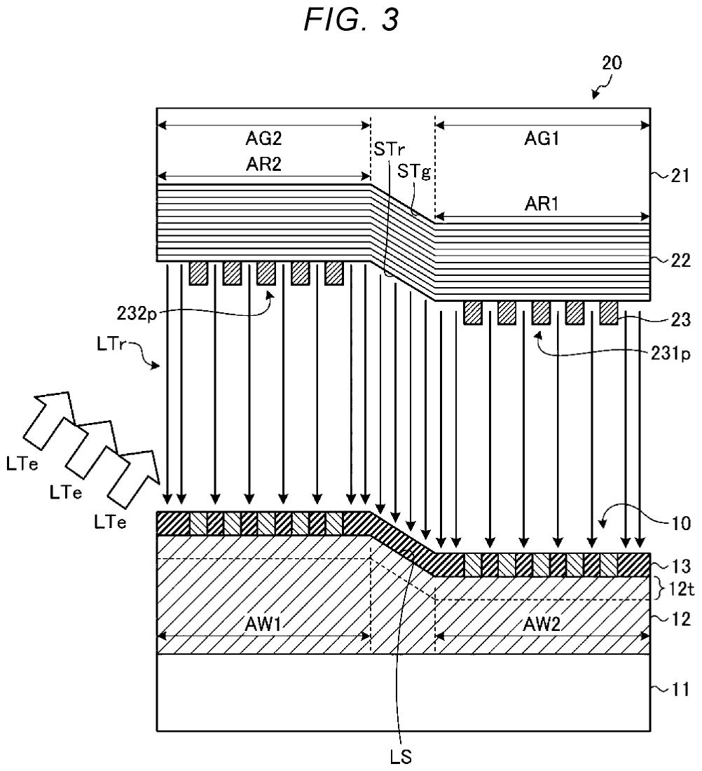

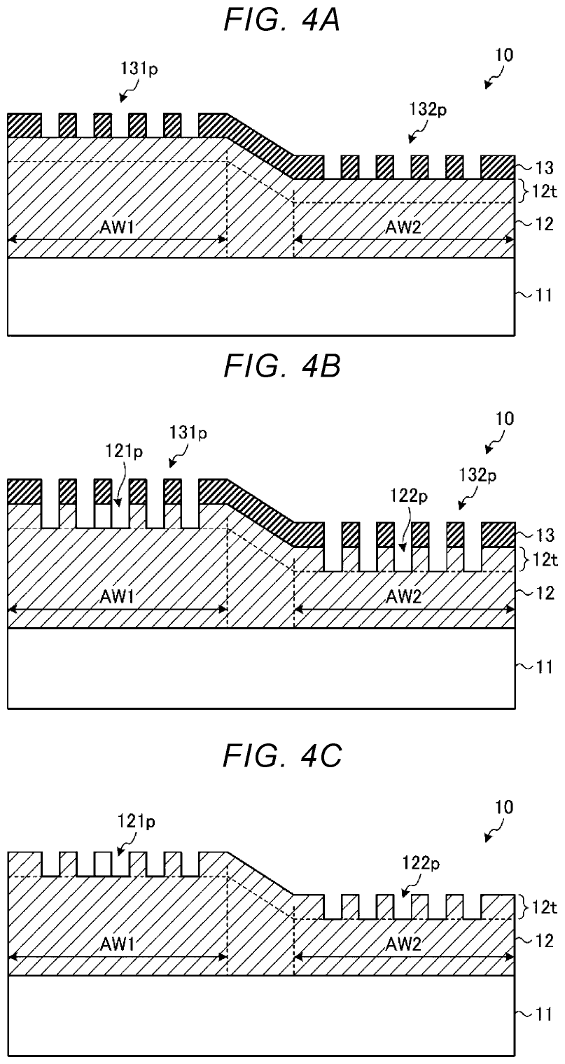

Next, a method of manufacturing the semiconductor device 10 of the embodiment will be described with reference to FIGS. 3 to 4C. FIGS. 3 to 4C are cross-sectional views illustrating part of the procedures of the method of manufacturing the semiconductor device 10 according to the embodiment.

In the example of FIG. 3, the exposure process is performed on the semiconductor device 10 that has undergone various processes to reach the state shown in FIG. 1, during manufacturing, by using the exposure mask 20 of the embodiment.

That is, the film 12 formed on the substrate 11 and including the layer to be processed 12t in the surface layer portion has already been formed on the semiconductor device 10. The film 12 has a local step LS, and the film thickness of the film 12 differs between the regions AW1 and AW2.

As shown in FIG. 3, for example, a negative photoresist layer 13 is formed on the film 12 of the semiconductor device 10. The photoresist layer 13 is formed using, for example, spin coating technology. Thus, the photoresist layer 13 having a uniform layer thickness can be formed over the entire surface of the film 12 where the local step LS is generated due to the film thickness difference.

The semiconductor device 10 and the exposure mask 20 are disposed at a predetermined distance from each other such that the surface of the exposure mask 20 on the side where the reflective layer 22 and the absorption layer 23 are provided faces the surface of the semiconductor device 10 on the side where the photoresist layer 13 is formed. Here, as described above, the horizontal positions of the semiconductor device 10 and the exposure mask 20 are adjusted such that the pattern 231p of the absorption layer 23 is transferred to the photoresist layer 13 on the region AW2 of the semiconductor device 10, and the pattern 232p is transferred to the photoresist layer 13 on the region AW1 of the semiconductor device 10.

In FIG. 3, the size of the semiconductor device 10 and the corresponding size of the exposure mask 20 are shown to be the same such that the positional relationship between the patterns 231p and 232p of the absorption layer 23 and the regions AW1 and AW2 of the semiconductor device 10 can be easily understood. However, as described above, the exposure mask 20 has a size, for example, about four times the size of the semiconductor device 10, and the patterns 231p and 232p of the exposure mask 20 are reduced and transferred to the photoresist layer 13.

With the semiconductor device 10 and the exposure mask 20 facing each other as described above, the exposure mask 20 is irradiated with an exposure light LTe from below the surface of the exposure mask 20 on which the reflective layer 22 and the absorption layer 23 are provided.

The exposure light LTe reaching the reflective layer 22 of the exposure mask 20 is reflected by the reflective layer 22 toward the semiconductor device 10, and the photoresist layer 13 on the film 12 is exposed by a reflected light LTr. The exposure light LTe reaching the absorption layer 23 of the exposure mask 20 is absorbed by the absorption layer 23 and does not reach the semiconductor device 10 side, and the photoresist layer 13 on the film 12 is not exposed.

Thus, the pattern 231p of the absorption layer 23 is transferred to the photoresist layer 13 formed on the region AW2 of the film 12. The pattern 232p of the absorption layer 23 is transferred to the photoresist layer 13 formed on the region AW1 of the film 12.

Here, in the regions AW1 and AW2, the film 12 has different thicknesses. Therefore, the photoresist layer 13 on the region AW1 and the photoresist layer 13 on the region AW2 have different focal depths, that is, different focus positions for the reflected light LTr.

Here, the region AG1 of the substrate 21 overlapping the pattern 231p of the absorption layer 23 in the height direction and the region AW2 of the film 12 are disposed at positions corresponding to each other. The region AG2 of the substrate 21 overlapping the pattern 232p of the absorption layer 23 in the height direction and the region AW1 of the film 12 are disposed at positions corresponding to each other.

Thus, both the reflected light LTr reaching the photoresist layer 13 at a position overlapping the region AW2 of the film 12 in the height direction from the reflective layer 22 at a position overlapping the region AG1 of the substrate 21 in the height direction, and the reflected light LTr reaching the photoresist layer 13 at a position overlapping the region AW1 of the film 12 in the height direction from the reflective layer 22 at a position overlapping the region AG2 of the substrate 21 in the height direction can be focused on respective photoresist layers 13 at different height positions.

In other words, according to the film thickness difference of the film 12 of the semiconductor device 10, the surface height of the reflective layer 22 of the exposure mask 20 is adjusted such that light is focused on the photoresist layer 13 in each of the regions AW1 and AW2 of the semiconductor device 10.

Therefore, the reflected light LTr is focused on both the photoresist layer 13 in the region AW1 and the photoresist layer 13 in the region AW2, and both patterns 231p and 232p are transferred to the photoresist layer 13 with high precision.

As shown in FIG. 4A, the exposed photoresist layer 13 is developed using the exposure mask 20 as described above to form patterns 131p and 132p in the photoresist layer 13, respectively. The pattern 131p is a pattern obtained by transferring the pattern 232p of the exposure mask 20, and the pattern 132p is a pattern obtained by transferring the pattern 231p of the exposure mask 20.

More specifically, the photoresist layer 13 is, for example, a negative photoresist layer. Therefore, the portion exposed to the input reflected light LTr reflected by the reflective layer 22 of the exposure mask 20 remains after the development process. The portion of the photoresist layer 13 that is not exposed due to absorption of the exposure light LTe by the absorption layer 23 of the exposure mask 20 is removed. Thus, the patterns 131p and 132p are thereby formed in the photoresist layer 13.

However, the photoresist layer 13 may be a positive photoresist layer. Here, the portion of the exposure mask 20 where the reflective layer 22 is exposed and the portion covered with the absorption layer 23 may be reversed from the above example. Thus, the patterns 131p and 132p shown in FIG. 4A can be similarly formed on the photoresist layer 13.

As shown in FIG. 4B, the layer to be processed 12t, which is the surface layer portion of the film 12, is etched through the patterns 131p and 132p of the photoresist layer 13. Thus, patterns 121p and 122p obtained by transferring the patterns 131p and 132p of the photoresist layer 13 are formed on the layer to be processed 12t. The patterns 121p and 122p can have shapes such as lines and spaces, holes, or dots each having a size of several tens of nm.

As shown in FIG. 4C, the photoresist layer 13 is removed by an ashing process using oxygen plasma or the like.

As described above, the exposure and development process and the etching process for the semiconductor device 10 of the embodiment are completed.

Thereafter, the semiconductor device 10 is manufactured by further forming various layers on the semiconductor device 10, and repeating processes such as processing the formed layers appropriately using photolithography technology and etching technology.

### Comparative Example

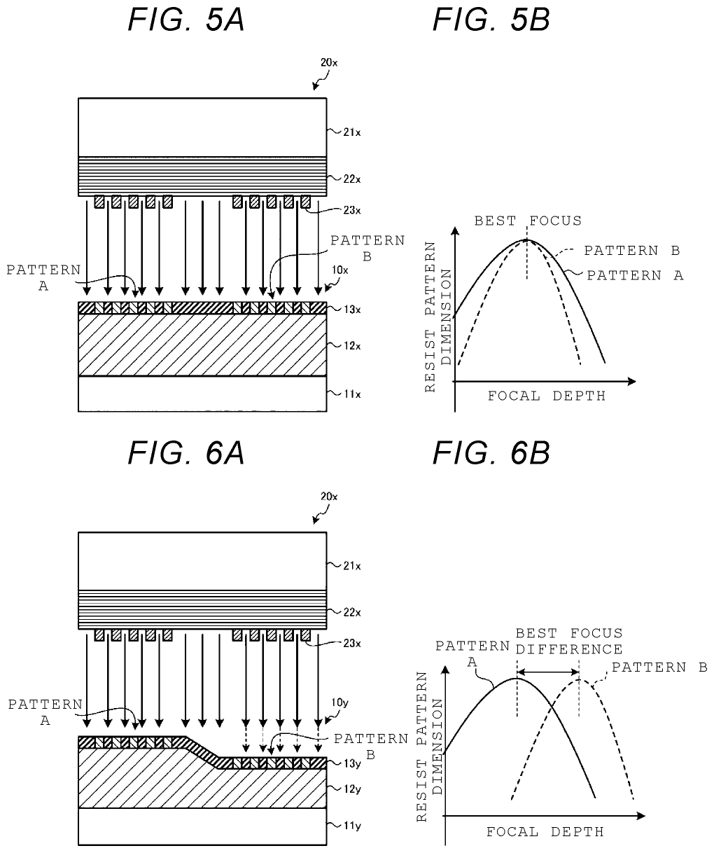

In the manufacturing process of semiconductor devices, EUV exposure technology is sometimes used to form a pattern of several tens of nm in a layer to be processed. In the EUV exposure technology, a reflective exposure mask that reflects exposure light to expose a photoresist layer is used instead of the transmissive exposure mask in the related art. FIGS. 5A to 6B show a configuration example of a reflective exposure mask 20x of a comparative example.

FIGS. 5A to 6B are cross-sectional views showing an example of the procedures of an exposure process using the exposure mask 20x according to the comparative example.

As shown in FIGS. 5A to 6B, the exposure mask 20x of the comparative example includes a flat substrate 21x having a uniform thickness over the entire surface, a reflective layer 22x provided on the substrate 21x and having a uniform layer thickness over the entire surface, and an absorption layer 23x provided on the reflective layer 22x and having patterns A and B.

In the example shown in FIGS. 5A and 5B, the exposure process is performed on a semiconductor device 10x using the exposure mask 20x.

As shown in FIG. 5A, the semiconductor device 10x includes a substrate 11x, and a film 12x formed on the substrate 11x and having a uniform thickness over the entire surface, and a photoresist layer 13x is further formed on the film 12x.

The surface of the exposure mask 20x on the side where the reflective layer 22x and the absorption layer 23x are formed faces the surface of the semiconductor device 10x on the side where the film 12x and the photoresist layer 13x are formed. The exposure mask 20x is irradiated with exposure light from the reflective layer 22x and absorption layer 23x side, and the photoresist layer 13x of the semiconductor device 10x is exposed by the reflected light reflected by the reflective layer 22x, thereby forming the patterns A and B on the photoresist layer 13x.

As shown in FIG. 5B, here, the best focus positions of the patterns A and B are the same in the portion where the pattern A is formed and the portion where the pattern B is formed of the photoresist layer 13x. Therefore, both patterns A and B are formed with high precision.

In the example shown in FIGS. 6A and 6B, the exposure process is performed on a semiconductor device 10y using the exposure mask 20x.

As shown in FIG. 6A, the semiconductor device 10y includes a substrate 11y, and a film 12y formed on the substrate 11y and having different film thicknesses for respective regions, and a photoresist layer 13y is further formed on the film 12y.

As in FIG. 5A, the exposure mask 20x and the semiconductor device 10y face each other, the exposure mask 20x is irradiated with exposure light, and the photoresist layer 13y of the semiconductor device 10y is exposed by the reflected light reflected by the reflective layer 22x to form the patterns A and B on the photoresist layer 13y. Here, the pattern A is formed on the thick portion of the film 12y, and the pattern B is formed on the thin portion of the film 12y.

As shown in FIG. 6B, here, the portion of the photoresist layer 13y where the pattern A is formed is closer to the pattern surface of the exposure mask 20x as compared with the portion where the pattern B is formed, and the best focus positions are different. Therefore, for example, when the reflected light is focused on the pattern A, for example, the pattern B is out of focus, thus it is difficult to focus the reflected light on both the patterns A and B.

According to the exposure mask 20 of the embodiment, the reflective layer 22 includes the region AR2 in which the surface height from the back surface of the substrate 21 is a predetermined height, and the region AR1 adjacent to the region AR2 via the step STr on the surface of the reflective layer 22, in which the surface height from the back surface of the substrate 21 is higher than the predetermined height. Thus, the focus margin during the exposure process can be improved, and light can be focused on the entire region of the photoresist layer 13 formed on the film 12 having the local step LS.

According to the exposure mask 20 of the embodiment, the substrate 21 includes the region AG2 that has a predetermined thickness and overlaps the region AR2 of the reflective layer 22 in the height direction, and the region AG1 that is adjacent to the region AG2 via the step STg of the main surface of the substrate 21 on the side where the reflective layer 22 and the like are provided, is thicker than the predetermined thickness, and overlaps the region AR1 of the reflective layer 22 in the height direction. Thus, the surface height of the reflective layer 22 in the regions AR1 and AR2 can be made different, and light can be focused on the photoresist layer 13 formed on the film 12 having the local step LS.

According to the exposure mask 20 of the embodiment, the step STr on the surface of the reflective layer 22 is a slope with an inclination angle of, for example, 0.01° or more and 5° or less. A slope with such an inclination angle can be obtained by adjusting the step STg on the surface of the substrate 21 to have a gentle inclination angle. As such, by making the step STg of the substrate 21 gentle, the influence of the step STg of the substrate 21 is reduced when the reflective layer 22 is formed on the surface of the substrate 21, and distortion or the like is prevented from occurring in the reflective layer 22, thereby forming the reflective layer 22 with uniform layer thickness throughout. Therefore, the reflection efficiency, refractive index, or the like of the reflective layer 22 with respect to the exposure light can be made uniform over the entire reflective layer 22.

According to the method of manufacturing the semiconductor device 10 of the embodiment, the wafer 1 and the exposure mask 20 are disposed such that the regions AR1 and AR2 of the exposure mask 20 and the plurality of regions AW1 and AW2 of the film 12 correspond to each other. More specifically, the wafer 1 and the exposure mask 20 are disposed such that the region AR2 of the exposure mask 20 corresponds to the region AW1 of the wafer 1, and the region AR1 of the exposure mask 20 corresponds to the region AR2 of the wafer 1.

Thus, the focus margin during the exposure process can be improved, and light can be focused on the entire region of the photoresist layer 13 formed on the film 12 having the local step LS.

According to the method of manufacturing the semiconductor device 10 of the embodiment, the difference in surface height of the reflective layer 22 in the regions AR1 and AR2 is two times or more and ten times or less the film thickness difference of the film 12 in the regions AW1 and AW2 of the wafer 1.

As described above, the film 12 formed on the semiconductor device 10 during manufacturing may have the local step LS that causes a film thickness difference of, for example, 50 nm or more and 100 nm or less. Accordingly, it is possible to focus light on the entire region of the photoresist layer 13 formed on the film 12 with the local step LS by adjusting the difference in the surface height of the reflective layer 22 of the exposure mask 20 to, for example, 120 nm or more and 1000 nm or less, and making the film thickness difference of the film 12 formed on the wafer 1 have two times or more and ten times or less the difference.

### Modification Example 1

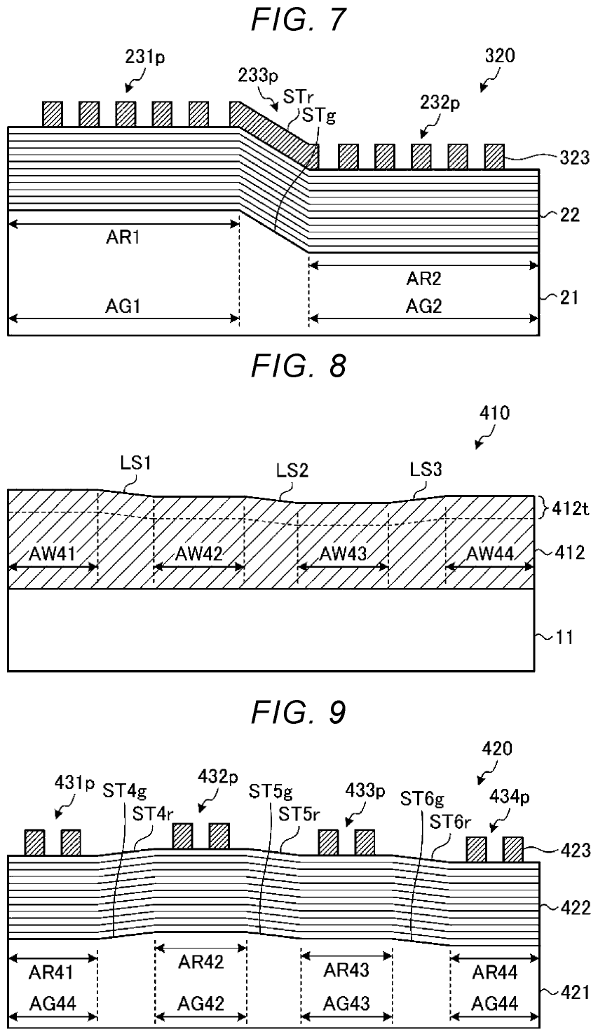

Next, an exposure mask 320 of Modification Example 1 of the embodiment will be described with reference to FIG. 7. The exposure mask 320 of Modification Example 1 differs from the above embodiment in that an absorption layer 323 is also formed in the portion of the reflective layer 22 where the step STr is formed.

In the drawings below, the same reference numerals are assigned to the same components as in the above-described embodiment, and the description thereof will be omitted.

FIG. 7 is a cross-sectional view showing an example of the configuration of the exposure mask 320 according to Modification Example 1 of the embodiment. As shown in FIG. 7, the exposure mask 320 of Modification Example 1 includes the substrate 21 such as a glass substrate, the reflective layer 22 formed on the substrate 21, and an absorption layer 323 formed on the reflective layer 22.

In the exposure mask 320 of Modification Example 1, the substrate 21 and the reflective layer 22 are configured in the same manner as in the above-described embodiment.

The absorption layer 323 has the patterns 231p and 232p on the regions AR1 and AR2 of the reflective layer 22, and a pattern 233p on the step STr of the reflective layer 22. The pattern 233p covers the entire step STr of the reflective layer 22, for example.

The absorption layer 323 may have the same layer thickness in the regions AR1 and AR2. On the other hand, the absorption layer 323 may have a layer thickness equal to the thickness of the regions AR1 and AR2 at the step STt, or may have a layer thickness different from the thickness of the regions AR1 and AR2. The layer thickness of the absorption layer 323 may change at the step STt.

The exposure mask 320 configured as described above can be manufactured, for example, as follows.

The substrate 21 and the reflective layer 22 are formed, for example, in the same manner as in the above embodiment. The absorption layer 323 is also formed, for example, in the same manner as in the above embodiment, except that the pattern 233p is formed on the step STr. Here, the layer thickness of the absorption layer 323 at the step STt may vary depending on the method and conditions for forming the absorption layer 323, as described above.

As described above, the exposure mask 320 of Modification Example 1 is manufactured.

According to the exposure mask 320 of Modification Example 1, the absorption layer 323 is also provided at the step STr of the reflective layer 22. Thus, it is possible to prevent the exposure light applied to the step STr of the reflective layer 22 from being diffusely reflected by the step STr and affecting the exposure process.

According to the exposure mask 320 of Modification Example 1, effects similar to the effects of the above-described embodiment are achieved.

The exposure mask 320 of Modification Example 1 described above includes the same substrate 21 and reflective layer 22 as in the above-described embodiment, but the structure of the absorption layer 323 of Modification Example 1 can also be applied to the exposure masks 120 and 220 of Modification Example 1 or Modification Example 2 described above.

Although the exposure mask 320 of Modification Example 1 described above has the absorption layer 323 having the same layer thickness in the regions AR1 and AR2, but as the absorption layer 223 of Modification Example 2 described above, the exposure mask 320 of Modification Example 1 may have the absorption layer 323 with different layer thicknesses in the regions AR1 and AR2.

### Modification Example 2

Next, an exposure mask 420 of Modification Example 2 of the embodiment will be described with reference to FIGS. 8 and 9. The exposure mask 420 of Modification Example 2 differs from the embodiment described above in that the exposure mask 420 is used for exposure process of a semiconductor device 410 having a plurality of local steps LS1 to LS3.

In the drawings below, the same reference numerals are assigned to the same components as in the above-described embodiments, and the description thereof will be omitted.

In the embodiment described above, the film 12 includes one local step LS. However, a film that includes various different types of layers gone through a plurality of processes may have a plurality of local steps due to the processes and the like that have been carried out so far. An example of such a semiconductor device 410 is shown in FIG. 8.

FIG. 8 is a cross-sectional view showing an example of the configuration of the semiconductor device 410 according to Modification Example 2 of the embodiment. FIG. 8 is a schematic diagram of a partial region of the semiconductor device 410 during manufacturing, showing a state before exposure and development process, for example.

As shown in FIG. 8, the semiconductor device 410 of Modification Example 2 includes the substrate 11 such as a silicon substrate, and a film 412 having a multilayer film structure in which a plurality of different types of layers are stacked, formed on the substrate 11, and having a layer to be processed 412t on the surface layer portion.

The film 412 includes a region AW41 having a predetermined thickness, a region AW42 as a sixth region thinner than the region AW41, a region AW43 as a fifth region further thinner than the region AW42, and a region AW44 thicker than the region AW43.

The regions AW41 and AW42 are adjacent to each other, and connected in series via a local step LS1 with a gentle slope on the surface of the film 412, for example. The regions AW42 and AW43 are adjacent to each other, and connected in series via a local step LS2 with a gentle slope on the surface of the film 412, for example. The regions AW43 and AW44 are adjacent to each other, and connected in series via a local step LS3 with a gentle slope on the surface of the film 412, for example.

The regions AW41 to AW44 can have various shapes including a rectangular shape. The minimum width of each of the regions AW41 to AW44 may be, for example, at least several μm. The film thickness difference of the film 412 in the regions AW41 to AW44 is, for example, 50 nm or more and 100 nm or less. However, the numerical values are only examples.

The number of local steps LS1 to LS3 in the semiconductor device 410 is merely an example, and may vary depending on the processes that the semiconductor device 410 has undergone so far and the stages of the manufacturing process. The film thickness and arrangement order of the regions AW41 to AW44 are only examples, and in the semiconductor device 410, regions with different thicknesses can be disposed in different orders, depending on the processes that the semiconductor device 410 has undergone so far and the stages of the manufacturing process.

FIG. 9 is a cross-sectional view showing an example of the configuration of the exposure mask 420 according to Modification Example 2 of the embodiment. The exposure mask 420 of Modification Example 2 is designed to correspond to the semiconductor device 410 described above, and is used for exposure process of the semiconductor device 410.

As shown in FIG. 9, the exposure mask 420 includes a substrate 421 such as a glass substrate, a reflective layer 422 formed on the substrate 421, and an absorption layer 423 formed on the reflective layer 422.

The substrate 421 includes a region AG41 having a predetermined thickness, a region AG42 having a predetermined thickness thicker than the thickness of the substrate 421 in the region AG41, a region AG43 having a predetermined thickness thinner than the region AG42, and a region AG44 having a predetermined thickness thinner than the thickness of the substrate 421 in the region AG43.

The regions AG41 and AG42 are adjacent to each other, and connected in series via, for example, a step ST4g with a gentle slope on the main surface of the substrate 421 on the reflective layer 422 and absorption layer 423 side. The regions AG42 and AG43 are adjacent to each other, and connected in series via, for example, a step ST5g with a gentle slope on the main surface of the substrate 421 on the reflective layer 422 and absorption layer 423 side. The regions AG43 and AG44 are adjacent to each other, and connected in series via, for example, a step ST6g with a gentle slope on the main surface of the substrate 421 on the reflective layer 422 and absorption layer 423 side.

The reflective layer 422 has, for example, a uniform thickness throughout. Thus, in the reflective layer 422, the surface heights from the back surface of the substrate 421 are different corresponding to the regions AG41 to AG44 and the steps ST4g to ST6g of the substrate 421.

That is, the reflective layer 422 includes a region AR41 as a third region that overlaps with the region AG41 of the substrate 421 in the height direction. In the region AR41, the reflective layer 422 has a predetermined height as a third height, as the surface height from the back surface of the substrate 421.

The reflective layer 422 includes a region AR42 as a second region that overlaps with the region AG42 of the substrate 421 in the height direction. In the region AR42, the reflective layer 422 has a predetermined height as a second height, which is higher than the surface height in the region AR41, as the surface height from the back surface of the substrate 421.

The reflective layer 422 includes a region AR43 as a first region that overlaps with the region AG43 of the substrate 421 in the height direction. In the region AR43, the reflective layer 422 has a predetermined height as a first height, which is lower than the surface height in the region AR42, as the surface height from the back surface of the substrate 421.

The reflective layer 422 includes a region AR44 that overlaps with the region AG44 of the substrate 421 in the height direction. In the region AR44, the reflective layer 422 has a predetermined height which is further lower than the surface height in the region AR43, as the surface height from the back surface of the substrate 421.

The difference in surface height of the reflective layer 422 in the regions AR41 to AR44 is, for example, two times or more and ten times or less the film thickness difference of the film 412 of the semiconductor device 410 described above. The regions AR41 to AR44 have similar shapes to the regions AW41 to AW44 in the film 412 of the semiconductor device 410, respectively. When the regions AR41 to AR44 are, for example, rectangular, the length of one side of each of the regions AR41 to AR44 is, for example, several hundred nm to several mm.

The reflective layer 422 has a step ST4r as a second step at a position overlapping the step ST4g of the substrate 421 in the height direction. The reflective layer 422 has a step ST5r as a first step at a position overlapping the step ST5g of the substrate 421 in the height direction. The reflective layer 422 has a step ST6r at a position overlapping the step ST6g of the substrate 421 in the height direction.

The steps ST4r to ST6r are gentle slopes with a predetermined inclination angle along the steps ST4g to ST6g of the substrate 421, respectively. Specifically, it is preferable that each of the steps ST4r to ST6r is a gentle slope with an inclination angle of 0.01° or more and 5° or less.

As an example of the size of the steps ST4r to ST6r, the widths of the steps ST4r to ST6r respectively sandwiched between the regions AR41 to AR44 can be set to, for example, 1 μm or more and several mm or less.

The absorption layer 423 is configured with patterns 431p to 434p on the regions AR41 to AR44 of the reflective layer 422, respectively. The absorption layer 423 may have a uniform layer thickness over the regions AR41 to AR44.

It is also possible to apply the configuration of the exposure mask 420 of Modification Example 2 having a plurality of steps ST4r to ST6r to the configuration of any one of Modifications Examples 1 to 3 described above. That is, an exposure mask having a plurality of steps ST4r to ST6r can be configured such that at least one of the substrate and the reflective layer has different thicknesses. An exposure mask having a plurality of steps ST4r to ST6r may include an absorption layer having different layer thicknesses in a plurality of regions.

Various configurations of the substrate 421, the reflective layer 422, and the absorption layer 423, and various numerical values related to the substrate 421, the reflective layer 422, and the absorption layer 423 can be the same as those of the substrate, the reflective layer, and the absorption layer of any of the embodiments and Modification Examples 1 to 3 described above.

The exposure mask 420 configured as described above can also be manufactured, for example, in the same manner as the exposure mask 20 of the above-described embodiment.

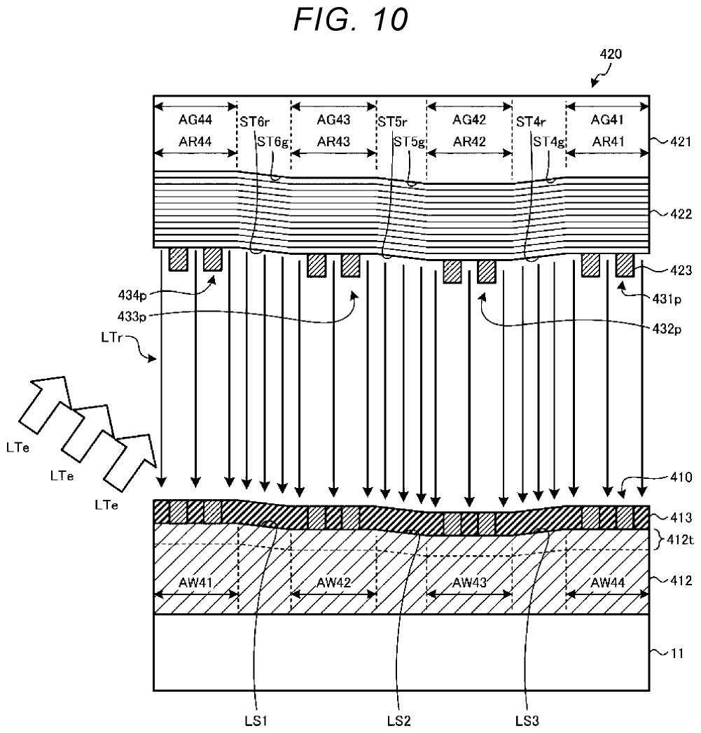

FIG. 10 is a cross-sectional view illustrating part of the procedures of a method of manufacturing the semiconductor device 410 according to Modification Example 2 of the embodiment. FIG. 10 shows how the semiconductor device 410 is exposed using the exposure mask 420.

As shown in FIG. 10, the exposure mask 420 and the semiconductor device 410 are disposed such that the side of the exposure mask 420 where the reflective layer 422 and the absorption layer 423 are provided faces a photoresist layer 413 formed on the film 412 of the semiconductor device 410. The exposure mask 420 is irradiated with the exposure light LTe from the side where the reflective layer 422 and the absorption layer 423 are provided, and the photoresist layer 413 of the semiconductor device 410 is exposed by the reflected light LTr reflected by the reflective layer 422.

Here, the positions of the exposure mask 420 and the semiconductor device 410 are such that the region AR44 where the surface height of the reflective layer 422 in the exposure mask 420 is lowest corresponds to the region AW41 where the thickness of the film 412 formed on the semiconductor device 410 is thickest. The region AR42 where the surface height of the reflective layer 422 in the exposure mask 420 is highest corresponds to the region AW43 where the thickness of the film 412 formed on the semiconductor device 410 is thinnest.

Thus, the region AR43 where the surface height of the reflective layer 422 in the exposure mask 420 is between the surface heights of the regions AR41 and AR44, and the region AW42 where the film thickness of the film 412 formed on the semiconductor device 410 is between the surface heights of the regions AW41 and AW44 are disposed at positions corresponding to each other. The region AR42 where the surface height of the reflective layer 422 in the exposure mask 420 is between the surface heights of the regions AR41 and AR44, and the region AW43 where the film thickness of the film 412 formed on the semiconductor device 410 is between the surface heights of the regions AW41 and AW44 are disposed at positions corresponding to each other.

By performing the exposure process here, the reflected light LTr is focused on any portion of the photoresist layer 413 formed in the regions AW41 to AW44 of the semiconductor device 410, and the patterns 431p to 434p of the exposure mask 420 are transferred to the photoresist layer 413 with high accuracy.

According to the exposure mask 420 of Modification Example 2, the reflective layer 422 further includes a region AR41 adjacent to the region AR42 via the step ST4r on the surface of the reflective layer 422, in which the surface height from the back surface of the substrate 421 is different from the surface height of the region AR42.

As such, the exposure mask 420 can have various configurations according to the number of local steps LS1 to LS3 of the semiconductor device 410, and the number and position of each of the plurality of regions AW41 to AW44 having different film thicknesses. Thus, it is possible to further improve the focus margin during the exposure process.

According to the exposure mask 420 of Modification Example 2, effects similar to the effects of the above-described embodiment are achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An exposure mask comprising:
a substrate having a first main surface on a first main surface side and a second main surface on a second main surface side opposite to the first main surface side;
a reflective layer disposed on the first main surface side and arranged to reflect exposure light; and
an absorption layer, having a predetermined pattern, disposed on the first main surface side via the reflective layer, the absorption layer arranged to absorb the exposure light, wherein
the reflective layer includes:
a first region having a first height, the first height being a surface height from the second main surface, and
a second region adjacent to the first region via a first step on a surface of the reflective layer, the second region having a second height from the second main surface, the second height being higher than the first height, and
the absorption layer is disposed in each of the first region and the second region.

2. The exposure mask according to claim 1, wherein
the substrate includes:
a third region having a first thickness and overlapping the first region in a height direction, and
a fourth region adjacent to the third region via a step on the first main surface, having a second thickness thicker than the first thickness, and overlapping the second region in the height direction.

3. The exposure mask according to claim 2, wherein
the reflective layer has a same thickness in the first region and the second region.

4. A pattern forming method using the exposure mask according to claim 1, the method comprising:
disposing a photoresist layer of a wafer, the wafer having a film including a layer to be processed and the photoresist layer formed in order to face a surface of the exposure mask on which the reflective layer and the absorption layer are disposed; and
irradiating the exposure mask with the exposure light from a side on which the reflective layer and the absorption layer are disposed, and exposing the photoresist layer by the exposure light reflected by the reflective layer to form the pattern of the absorption layer in the photoresist layer, wherein
the film includes a plurality of regions with different film thicknesses in an exposure region where one exposure is performed, and
when the wafer and the exposure mask are opposed to each other, the wafer and the exposure mask are disposed such that the first region and the second region of the exposure mask correspond to the plurality of regions of the film, respectively.

5. A method of manufacturing a semiconductor device using the exposure mask according to claim 1, the method comprising:
disposing a photoresist layer of a wafer, the wafer having a film including a layer to be processed and the photoresist layer formed in order to face a surface of the exposure mask on which the reflective layer and the absorption layer are disposed; and
irradiating the exposure mask with the exposure light from a side on which the reflective layer and the absorption layer are disposed, and exposing the photoresist layer by the exposure light reflected by the reflective layer to form the pattern of the absorption layer in the photoresist layer, wherein
the film includes a plurality of regions with different film thicknesses in an exposure region where an exposure is performed, and
when the wafer and the exposure mask are opposed to each other, the wafer and the exposure mask are disposed such that the first region and the second region of the exposure mask correspond to the plurality of regions of the film, respectively.

6. The exposure mask according to claim 1, wherein the exposure mask is an extreme ultraviolet exposure mask.

7. The exposure mask according to claim 1, wherein the substrate includes a glass material.

8. The exposure mask according to claim 1, wherein the exposure mask is a reflective exposure mask.

9. The exposure mask according to claim 1, wherein the reflective layer is a multilayer including a plurality of sublayers.

10. The exposure mask according to claim 9, wherein the plurality of sublayers include sublayers of different materials.

11. The exposure mask according to claim 10, wherein the sublayers of different materials are arranged in an alternating manner.

12. The exposure mask according to claim 1, wherein the absorption layer is formed of TaN, TaBN, or TaGeN.

13. The exposure mask according to claim 1, wherein first step has an inclination angle of 0.01° or more and 5° or less.
